(19) United States
(12) Patent Application Publication
(10) Pub. No.: US 2025/0219394 A1
(43) Pub. Date: Jul. 3, 2025

(54) METHOD, CIRCUIT, AND DEVICE FOR PROTECTING MOS GROUP, AND CHARGING AND DISTRIBUTION SYSTEM

(71) Applicant: SAIC GM WULING AUTOMOBILE CO., LTD., Liuzhou, Guangxi (CN)

(72) Inventors: Changye Liu, Liuzhou (CN); Min Wei, Liuzhou (CN); Guodong Wang, Liuzhou (CN); Shanxuan Huang, Liuzhou (CN); Shuangming Sun, Liuzhou (CN); Jinjiang Chen, Liuzhou (CN)

(73) Assignee: SAIC GM WULING AUTOMOBILE CO., LTD., Liuzhou, Guangxi (CN)

(21) Appl. No.: 18/994,840

(22) PCT Filed: Jul. 31, 2024
(86) PCT No.: PCT/CN2024/108678

§ 371 Date: Jan. 15, 2025

(30) Foreign Application Priority Data
Jan. 3, 2024 (CN) 202410008513.0

(51) Int. Cl. H02H 7/12

(52) U.S. Cl. CPC H02H 7/1213

(57) ABSTRACT

Provided is a method, a circuit, and a device for protecting a MOS group. The method includes: disconnecting a power supply switch to set a DC-DC chip in an off state; controlling input of a target power supply, and when determining that the voltage signal of the target power supply satisfies the preset condition, determining whether a voltage signal of the target power supply satisfies a preset condition; turning on the power supply switch and supplying, by a chip power supply, power to the DC-DC chip. When the voltage signal of the target power supply satisfies the preset condition, a connection switch is turned on, and the DC-DC chip is connected to a power supply circuit; and when the DC-DC chip is powered on, turning on a target MOS group, and converting a DC voltage signal output by the target power supply into a pulse electrical signal.

This application is a continuation of International Application No. PCT/CN2024/108678, filed on Jul. 31, 2024, which claims priority to Chinese Patent Application No. 202410008513.0, filed on Jan. 3, 2024, the contents of which are incorporated herein by reference in their entireties.

### TECHNICAL FIELD

The present disclosure relates to the field of charging and distribution technologies, and in particular, to a method, a circuit, and a device for protecting a MOS group, and a charging and distribution system.

### BACKGROUND

New energy vehicles refer to vehicles that use unconventional fuels as a power source. Under the social development prospects of energy pressure and environmental protection, new energy vehicles will undoubtedly become the development trend of future vehicles. A low-power charging and distribution system of the new energy vehicles is typically equipped with a direct current to direct current (DC-DC) converter full-bridge metal oxide semiconductor (MOS) group.

A DC power output by a target power supply passes through the full-bridge MOS group and a transformer. Two diagonal MOS transistors in the full-bridge MOS group form one group, with two groups in total, and these groups are alternately conducted to convert a DC power signal into a pulse electrical signal by the transformer. The existing DC-DC full-bridge MOS group generally selects a MOS with a withstand voltage of 200V. However, at the moment of power-up, a voltage higher than the withstand voltage of 200V of the MOS transistor is generated, thereby causing damage to the full-bridge MOS group.

In order to avoid the damage of the full-bridge MOS group, a MOS with a higher withstand voltage or a power-up delay control strategy is generally selected in the prior art. Selecting a full-bridge MOS group with the higher withstand voltage means that the cost of the product will significantly increase, and using the power-up delay control strategy can only provide protection during the power-up time. During other procedures, the full-bridge MOS group may still be damaged due to over-voltage or over-current.

### SUMMARY

Embodiments of the present disclosure provide a method, a circuit and a device for protecting a MOS group, and a charging and distribution system, for solving the problem that a full-bridge MOS group is easily damaged due to over-voltage or over-current in the prior art.

According to a first aspect, an embodiment of the present disclosure provides a method for protecting a MOS group, including: disconnecting a power supply switch to set a direct current to direct current (DC-DC) chip in an off state; controlling an input of a target power supply, and determining whether a voltage signal of the target power supply satisfies a preset condition; when determining that the voltage signal of the target power supply satisfies the preset condition, turning on the power supply switch and supplying, by a chip power supply, power to the DC-DC chip, when the voltage signal of the target power supply satisfies the preset condition, a connection switch is turned on, and the DC-DC chip is connected to a power supply circuit; and when the DC-DC chip is powered on and activated, turning on a target MOS group and converting a DC voltage signal output by the target power supply into a pulse electrical signal.

Optionally, said when the voltage signal of the target power supply satisfies the preset condition, a connection switch is turned on includes: when the voltage signal of the target power supply is both in a non-over-voltage state and in a non-under-voltage state, the voltage signal of the target power supply satisfies the preset condition, and the connection switch is turned on.

Optionally, said determining whether a voltage signal of the target power supply satisfies a preset condition includes: collecting, by a sampling circuit, the voltage signal of the target power supply; and determining that the voltage signal of the target power supply satisfies the preset condition in response to the voltage signal of the target power supply being within an operating voltage range.

Optionally, after the DC-DC chip is powered on and activated, the method further includes: when the voltage signal of the target power supply does not satisfy the preset condition, disconnecting the power supply switch and/or the connection switch and turning on the DC-DC chip. The power supply switch is turned off under control of a micro control unit (MCU), and the connection switch is automatically turned off based on a circuit structure.

Optionally, said turning on the power supply switch, and supplying power to the DC-DC chip includes: turning on the power supply switch to supply power to the DC-DC chip after a preset time when determining that the voltage signal satisfies the preset condition.

According to a second aspect, an embodiment of the present disclosure provides a circuit for protecting a MOS group, including: a micro control unit (MCU) configured to control a power supply switch to be turned off before determining whether a voltage signal of a target power supply satisfies a preset condition, and control the power supply switch to be turned on after determining that the voltage signal of the target power supply satisfies the preset condition; a connection switch configured to be turned on when the voltage signal of the target power supply satisfies the preset condition, and connect a direct current to direct current (DC-DC) chip to a power supply circuit to supply power to the DC-DC chip; and the power supply switch, configured to be turned off or turned on under control of the MCU to supply power to the DC-DC chip through a chip power supply. When the DC-DC chip is powered on and activated, a target MOS group is turned on, and a DC voltage signal output by the target power supply is converted into a pulse electrical signal.

Optionally, an input end of the connection switch is connected to a, and the determination circuit includes: an under-voltage determination circuit configured to output a low-level signal to the connection switch when determining that the voltage signal is in a non-under-voltage state, and output a high-level signal to the connection switch when determining that the voltage signal is in an under-voltage state; an over-voltage determination circuit configured to output a low-level signal to the connection switch when determining that the voltage signal is in a non-over-voltage state, and output a high-level signal to the connection switch when determining that the voltage signal is in an over-voltage state; and a connection switch configured to be turned on when the under-voltage determination circuit and the over-voltage determination circuit simultaneously output a low-level signal, and to be turned off otherwise.

Optionally, the under-voltage determination circuit includes a first voltage comparator, and the over-voltage determination circuit includes a second voltage comparator. A first input end of the first voltage comparator is connected to the target power supply, a second input end of the first voltage comparator is connected to the chip power supply, and the first voltage comparator is configured to compare a voltage signal output by the target power supply with a first reference voltage signal of the chip power supply to determine whether the target power supply is in the under-voltage state. A first input end of the second voltage comparator is connected to the chip power supply, a second input end of the second voltage comparator is connected to the target power supply, and the second voltage comparator is configured to compare a voltage signal output by the target power supply with a second reference voltage signal of the chip power supply to determine whether the target power supply is in the over-voltage state.

Optionally, the under-voltage determination circuit and the over-voltage determination circuit further include: a hysteresis circuit configured to feed back a reference voltage signal input by the chip power supply to prevent frequent under-voltage disconnections of the circuit caused by voltage fluctuation.

Optionally, the circuit for protecting a MOS group further includes: a sampling circuit connected between the target power supply and the MCU, and configured to collect the voltage signal of the target power supply, and send the collected voltage signal to the MCU.

Optionally, an input end of the power supply circuit is the chip power supply, and an output end of the power supply circuit is connected to the power supply switch, and the power supply circuit is configured to supply power to the DC-DC chip when the power supply switch and the connection switch are turned on.

According to a third aspect, an embodiment of the present disclosure provides a device for protecting a MOS group, including: at least one processor; and at least one memory in communication with the processor. The memory stores program instructions executable by the processor, and the processor, when invoking the program instructions, is configured execute the method according to any one of the first aspect.

According to a fourth aspect, an embodiment of the present disclosure provides a charging and distribution system, including: the circuit for protecting the MOS group according to any one of the second aspect.

According to the embodiments of the present disclosure, the power supply switch and the connection switch are provided, so that when whether the voltage output by the target power supply satisfies the preset condition is actively obtained and monitored, the switch can be automatically turned off through the circuit structure when the voltage does not satisfy the preset condition, thereby improving the reliability of circuit safety, and realizing the protection of the target MOS group. Meanwhile, the set double-loop determination can adjust the DC-DC chip to the off state when either the under-voltage state or the over-voltage state occurs, thereby preventing the full-bridge MOS group from being damaged in the over-voltage state or the under-voltage state.

### BRIEF DESCRIPTION OF DRAWINGS

In order to more clearly describe the technical solutions of embodiments of the present disclosure, the following briefly describes the accompanying drawings desired in the embodiments. It is appreciated that, the accompanying drawings described below are merely some embodiments of the present disclosure, and for those skilled in the art, other accompanying drawings can be obtained based on these accompanying drawings without creative effort.

FIG. 1 is a circuit diagram of a DC-DC full-bridge MOS group;

FIG. 2 is a schematic diagram of a circuit for protecting a MOS group according to an embodiment of the present disclosure;

FIG. 3 is a schematic diagram of another circuit for protecting a MOS group according to an embodiment of the present disclosure;

FIG. 4 is a flowchart of a method for protecting a MOS group according to an embodiment of the present disclosure;

FIG. 5 is a schematic diagram of another circuit for protecting a MOS group according to an embodiment of the present disclosure; and

FIG. 6 is a structural schematic diagram of an electronic device according to an embodiment of the present disclosure.

### DESCRIPTION OF EMBODIMENTS

In order to better understand technical solutions of the present disclosure, the embodiments of the present disclosure are described in details with reference to the accompanying drawings.

It is to be made clear that the described embodiments are only some rather than all of the embodiments of the present disclosure. Based on the embodiments the present disclosure, all other embodiments obtained by those skilled in the art without any creative efforts fall within the protection scope of the present disclosure.

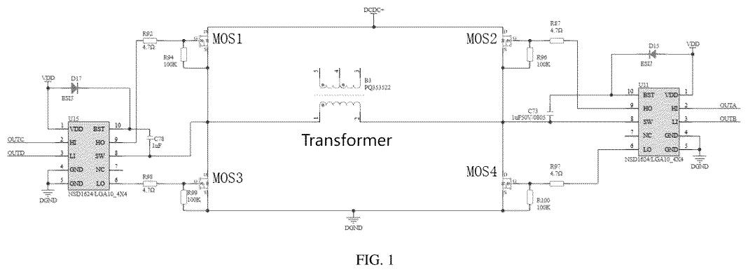

A low-power charging and distribution system of a new energy vehicle is typically equipped with a DC-DC full-bridge MOS group. A DC power output by a target power supply passes through the full-bridge MOS group and a transformer. Two diagonal MOS transistors in the full-bridge MOS group form one group, with two groups in total, and these groups are alternately conducted to convert a DC power signal into a pulse electrical signal by the transformer. FIG. 1 is a circuit diagram of a DC-DC full-bridge MOS group. Referring to FIG. 1, the DC power of a DC-DC+power supply passes through the full-bridge MOS group and the transformer. MOS1 and MOS4 form one group, and MOS2 and MOS3 form one group, which are alternately conducted to convert the DC power signal into the pulse electrical signal by the transformer. The existing DC-DC full-bridge MOS group generally selects a MOS with a withstand voltage of 200V. However, at the moment of power-up, a voltage higher than the withstand voltage of 200V of the MOS transistor is generated, thereby causing damage to the full-bridge MOS group.

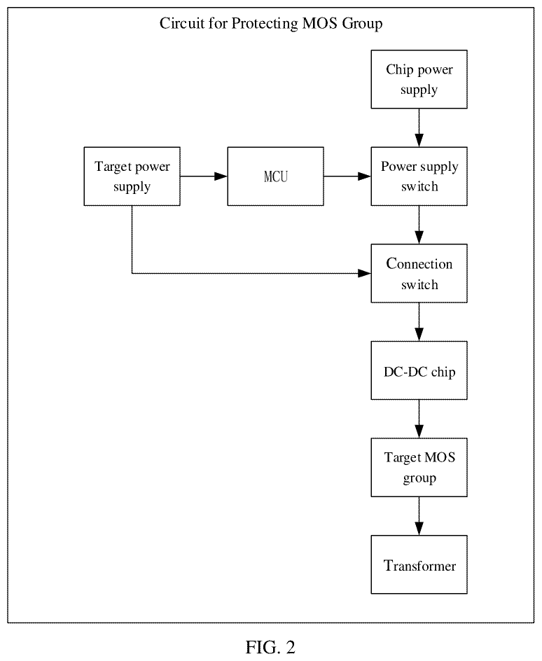

FIG. 2 is a schematic diagram of a circuit for protecting a MOS group according to an embodiment of the present disclosure. Referring to FIG. 2, the circuit for protecting a MOS group includes a target power supply, a chip power supply, a micro control unit (MCU), a connection switch, a power supply switch, and a DC-DC chip.

The target power supply is configured to input a voltage signal to be converted. In an example, the DC power signal input by the target power supply is conducted to the transformer through a target MOS group connected by a pin of the DC-DC chip, and the DC power signal is converted into the pulse electrical signal by the transformer.

The chip power supply is configured to supply power to the DC-DC chip, so that the DC-DC chip is in an on state.

The DC-DC chip is configured to conduct the connected target MOS group and the transformer connected to the target MOS group in the power-on state, so that the transformer can convert the DC power signal output by the target power supply into the pulse electrical signal. When in an off state, the DC-DC chip cannot conduct the voltage output by the target power supply to the target MOS group and the transformer, preventing the MOS group from being burned by the voltage output by the target power supply.

The MCU is configured to control on/off of the power supply circuit by controlling on/off of the power supply switch, and further protect the target MOS group by on/off of the DC-DC chip. In an example, the MCU is configured to determine whether a voltage applied by the target power supply satisfies the preset condition. The power supply switch is controlled to be turned off before determining whether the voltage of the target power supply satisfies the preset condition, and the power supply switch is controlled to be turned on after determining that the voltage of the target power supply satisfies the preset condition, to supply power to the DC-DC chip.

The power supply switch is configured to be turned on or turned off under the control of the MCU. When being turned on, the DC-DC chip is powered by the chip power supply, the DC-DC chip is turned on, and the target MOS group is turned on. When being turned off, the DC-DC chip is stopped from being powered, the DC-DC chip is turned off, and no DC power passes through the target MOS group, preventing the target MOS group from being burnt.

The connection switch is configured to automatically turn on when the voltage of the target power supply satisfies the preset condition and automatically turn off when the voltage of the target power supply does not satisfy the preset condition according to the designed circuit structure. When the connection switch is turned on, the DC power output by the target power supply is transmitted to the DC-DC chip. When the connection switch is turned off, the DC-DC chip is disconnected from the chip power supply, and the DC-DC chip is turned on, preventing the target power supply from burning the target MOS group.

According to the embodiments of the present disclosure, both the power supply switch and the connection switch are provided, so that it is possible to determine whether the voltage output by the target power supply satisfies the preset condition is actively obtained and monitored, and the switch can be automatically turned off through the circuit structure when the voltage does not satisfy the preset condition, thereby improving the reliability of circuit safety, and realizing the protection of the target MOS group.

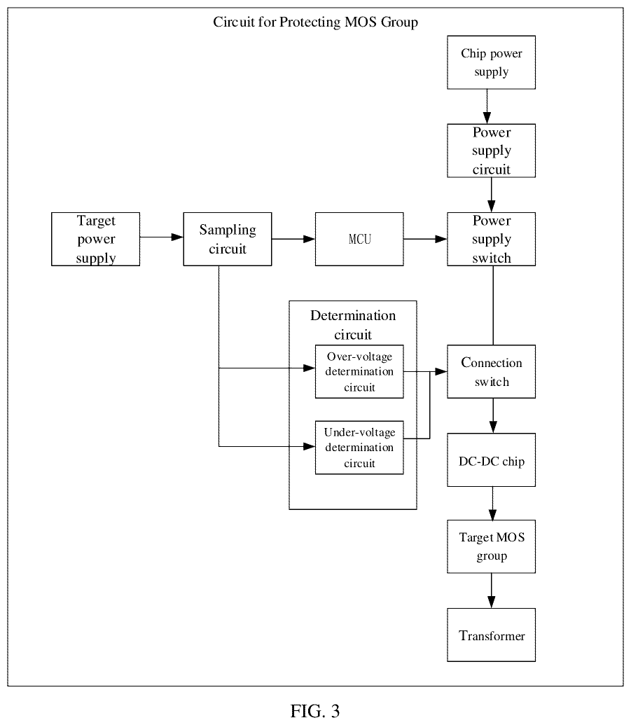

FIG. 3 is a schematic diagram of another circuit for protecting a MOS group according to an embodiment of the present disclosure. Referring to FIG. 3, in addition to the target power supply, the chip power supply, the MCU, the connection switch, the power supply switch and the DC-DC chip, the circuit for protecting the MOS group further includes: a determination circuit, a sampling circuit and a power supply circuit.

The output end of the determination circuit is connected to the input end of the connection switch, and is configured to control on or off of the connection switch through the circuit structure. The determination circuit specifically includes an under-voltage determination circuit and an over-voltage determination circuit.

The under-voltage determination circuit is configured to output a low-level signal to the connection switch when the voltage signal is in a non-under-voltage state, and output a high-level signal to the connection switch when the current signal is in an under-voltage state.

The over-voltage determination circuit is configured to output a low level signal to the connection switch when the voltage signal is in a non-over-voltage state, and output a high level signal to the connection switch when the voltage signal is in an over-voltage state.

The connection switch is only turned on when the over-voltage determination circuit and the under-voltage determination circuit simultaneously output a low level signal, otherwise the connection switch is turned off. In other words, when any one or both of the over-voltage determination circuit and the over-current determination circuit output a high level signal, the connection switch is turned off. Generally, the connection switch is a MOS transistor. The connection switch is turned on when the MOS transistor is turned off, and the connection switch is turned off when the MOS transistor is turned on.

The under-voltage determination circuit is provided with a first voltage comparator. A first input end of the first voltage comparator is connected to the target power supply and configured to receive a voltage signal output by the target power supply. A second input end of the first voltage comparator is connected to the chip power supply and configured to receive a first reference voltage signal. The first voltage comparator is configured to compare the received voltage signal with the first reference voltage signal. When the voltage signal is less than the first reference voltage signal, the voltage signal is in the under-voltage state and outputs a high level to the connection switch. When the voltage signal is greater than the first reference signal, the voltage signal is in the non-under-voltage state and outputs a low level to the connection switch. Generally, the first reference voltage signal may be set to 60V.

The over-voltage determination circuit is provided with a second voltage comparator. A first input end of the second voltage comparator is connected to the chip power supply and configured to receive a second reference voltage signal. A second input end of the voltage comparator is connected to the target power supply and configured to receive a voltage signal output by the target power supply. The second voltage comparator is configured to compare the received voltage signal with the second reference voltage signal. When the voltage signal is less than the second reference voltage signal, the voltage signal is in the non-over-voltage state and outputs a low level to the second switch. When the voltage signal is greater than the second reference voltage signal, the voltage signal is in the over-voltage state and outputs a high level to the second switch. Generally, the second reference voltage signal may be set to 160V.

The sampling circuit is configured to collect a voltage signal of the target power supply and output the collected voltage signal to the MCU, the first voltage comparator and the second voltage comparator.

The input end of the power supply circuit is the chip power supply, and the output end of the power supply circuit is connected to the power supply switch, and the power supply circuit is configured to supply power to the DC-DC chip when the power supply switch and the connection switch are turned on.

Optionally, a hysteresis circuit is further provided in the under-voltage determination circuit and the over-voltage determination circuit, and is configured to feed back a reference voltage signal input by an auxiliary power supply, to prevent frequent disconnection of under-voltage circuits caused by voltage fluctuation.

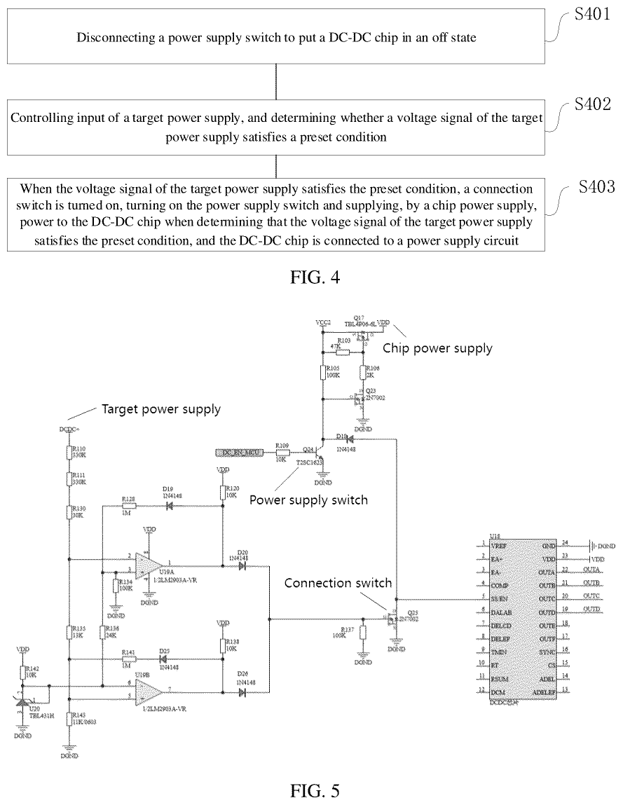

FIG. 4 shows a method for protecting a MOS group according to an embodiment of the present disclosure. The method is applied to the MCU shown in FIG. 2 and FIG. 3, and in combination with the circuit for protecting the MOS group shown in FIG. 2 and FIG. 4, the method specifically includes:

S401, disconnecting a power supply switch to set a DC-DC chip in an off state.

S402, controlling an input of a target power supply, and determining whether a voltage signal of the target power supply satisfies a preset condition.

In an example, the MCU is configured to control the target power supply to input the voltage signal, collect the voltage of the target power supply through the sampling circuit, and compare the collected voltage with a preset voltage operating range to determine whether the voltage of the target power supply satisfies the preset condition.

S403: turning on the power supply switch and supplying, by a chip power supply, power to the DC-DC chip when determining that the voltage signal of the target power supply satisfies the preset condition. When the voltage signal of the target power supply satisfies the preset condition, a connection switch is turned on, and the DC-DC chip is connected to a power supply circuit.

In an example, when the voltage of the target power supply is within the preset voltage operating range, it is determined that the voltage of the target power supply satisfies the preset condition, and a control instruction is sent to the power supply switch to turn on the power supply switch and control the chip power supply to supply power to the DC-DC.

Optionally, when determining that the voltage satisfies the preset condition, the power supply switch is turned on after a preset time, to reduce sensitivity and prevent the target MOS group from being burned. The preset time is generally set to 10 ms.

When the voltage signal of the target power supply satisfies the preset condition, that is, the voltage signal of the target power supply is both in the non-over-voltage state and is in the non-under-voltage state, the connection switch is turned on based on the low-level signals sent by the under-voltage determination circuit and the over-voltage determination circuit, and the DC-DC chip is connected to the power supply circuit. The chip power supply supplies power to the DC-DC chip after the power supply switch is turned on.

That is, only when the power supply switch and the connection switch are turned on at the same time, the DC-DC chip is connected to the power supply circuit, and the chip power supply starts to supply power to the DC-DC chip and the DC-DC chip is turned on. The voltage signal output by the target power supply is transmitted to the target MOS group connected to a pin of the DC-DC chip through the DC-DC chip, and is converted into a pulse electrical signal by a transformer conducted by the MOS.

After the DC-DC chip is turned on, the MCU continues to collect the voltage of the target power supply through the voltage sampling circuit, and determines in real time whether the voltage of the target power supply satisfies the preset condition. When the preset condition is met, the power supply switch is kept turned on, and the DC-DC chip is turned on. When the preset condition is not met, the power supply switch is turned off to stop the power supply to the DC-DC chip, the DC-DC chip is turned off, and the voltage output by the target power supply cannot be continuously transmitted to the target MOS group, thereby protecting the target MOS group from being burnt.

The under-voltage determination circuit and the over-voltage determination circuit determine whether the circuit is in the under-voltage state or the over-voltage state, respectively. When the voltage of the target power supply is in the non-under-voltage state, the first voltage comparator in the under-voltage determination circuit outputs a low level to the connection switch. When the voltage of the target power supply is in the under-voltage state, the first voltage comparator outputs a high level to the connection switch. When the voltage of the target power supply is in the non-over-voltage state, the second current comparator in the over-voltage determination circuit outputs a low level to the second switch. When the voltage of the target power supply is in the over-voltage state, the second current comparator outputs a high level to the second switch.

The DC-DC chip is turned on when the connection switch simultaneously receives the low level signals sent by the over-voltage determination circuit and the over-current determination circuit. The DC-DC chip is turned off when the connection switch receives the high level signal sent by any one of the under-voltage determination circuit and the over-voltage determination circuit or the high level signal sent simultaneously.

According to the embodiments of the present disclosure, the power supply switch and the connection switch are arranged, respectively, so that when whether the voltage output by the target power supply satisfies the preset condition is actively obtained and monitored, the switch can be automatically turned off through the circuit structure when the voltage does not satisfy the preset condition, thereby improving the reliability of circuit, and realizing the protection of the target MOS group. Meanwhile, the double-loop determination can adjust the DC-DC chip to the off state when either the under-voltage state or the over-voltage state occurs, thereby preventing the full-bridge MOS group from being damaged in either the over-voltage state or the under-voltage state.

FIG. 5 is a circuit diagram of a specific circuit for protecting a MOS group according to an embodiment of the present disclosure. An embodiment of the specific circuit for protecting the MOS group is described below with reference to FIG. 4. The connection switch is a MOS transistor Q25, the power supply switch is a triode Q24, the target power supply is DC-DC+, and the chip power supply is VDD.

The MCU is powered on to initialize the MCU for preparation. The MCU controls the power supply switch to be turned off to disconnect the power supply circuit. In an example, the MCU outputs EN=1, and controls the power supply switch, i.e., a triode Q24, to be grounded. The voltages of G terminal (gate) and S terminal (source) of the MOS transistor Q23 are consistent, and the MOS transistor Q23 is turned off. A resistor R106 is not connected to the circuit after the MOS transistor Q23 is turned off. The voltages of G terminal and S terminal of the MOS transistor Q17 are consistent, and the MOS transistor Q17 is turned off. The circuit between the chip power supply VDD and VCC2 is turned off, VDD cannot supply power to the DC-DC chip, and the DC-DC chip remains in the off state.

The MCU controls the target power supply, i.e., DC-DC+power supply input, and determines whether the voltage signal of DC-DC+satisfies the preset condition. In an example, a voltage signal of the DC-DC+power supply is transmitted to the MCU by providing a sampling circuit in the DC-DC+power supply circuit, and the MCU determines whether the voltage signal is within an operating voltage range. If the voltage signal is within the operating voltage range, the delay is 10 ms, EN=0 is output, and the triode Q24 is controlled not to be grounded. A voltage difference occurs between the G terminal and the S terminal of the MOS transistor Q23, and the MOS transistor Q23 is turned on. A voltage difference occurs between the G terminal and the S terminal of the MOS transistor Q17, and the MOS transistor Q17 is turned on. A circuit between VDD and VCC2 is connected, and the VDD supplies power to the DC-DC chip.

The voltage signal output by the DC-DC+power supply is further output to the determination circuit for double-loop comparison. If the determination result includes the over-voltage state or the under-voltage state, the MOS transistor Q25 is turned off by the connection switch, so that the enable of a SS/EN pin is pulled down, and the DC-DC chip is kept in the off state. If the determination result is determined to be in the non-over-voltage state and the non-under-voltage state, the SS/EN pin is kept connected to the triode Q24.

In an example, a first voltage comparator, namely, a voltage comparator U19A, is provided in the under-voltage determination circuit in the determination circuit. The sampling circuit sends the real-time voltage signal of the DC-DC+power supply circuit to a terminal 2 (“− terminal”) of the voltage comparator U19A, and the terminal 3 (“+ terminal”) of the voltage comparator U19A is connected to the first reference voltage signal to compare the first reference voltage signal with the real-time voltage signal. When the voltage signal is less than the reference voltage signal, a high level is output, which is regarded as 1 and recorded as an under-voltage state. The voltage at the G terminal of the MOS transistor Q25 is pulled up, and there is a voltage difference between the voltage at the G terminal and the S terminal. The MOS transistor Q25 is turned on, and the SS/EN pin is grounded and enabled to be pulled down, so that the DC-DC chip is in the off state. When the real-time voltage signal is greater than the reference voltage signal, a low level is output, which is regarded as 0 and recorded as a non-under-voltage state. The voltage at the G terminal of the MOS transistor Q25 is pulled down, which is consistent with the voltage between the S terminal, and the SS/EN pin is kept connected to the triode Q24. A hysteresis circuit, namely, a diode D19, a resistor R128, a resistor R120 and VDD, is provided between a terminal 1 and a terminal 3 of the voltage comparator U19A. The hysteresis circuit has a feedback function to prevent frequent under-voltage disconnection of the circuit caused by voltage fluctuation.

A second voltage comparator, namely, a voltage comparator U19B, is provided at the over-voltage determination circuit in the determination circuit. The sampling resistor sends the real-time voltage signal of the DC-DC+power supply circuit to a terminal 5 (“+ terminal”) of the voltage comparator U19B, and a terminal 6 (“− terminal”) of the voltage comparator U19B is connected to the second reference voltage signal to compare the second reference voltage signal with the real-time voltage signal. When the real-time voltage signal is greater than the second reference voltage signal, a high level is output, which is regarded as 1 and recorded as an over-voltage state. The voltage at the G terminal of the MOS transistor Q25 is pulled up, and there is a voltage difference between the voltage at the G terminal and the S terminal. The MOS transistor Q25 is turned on, and the SS/EN pin is grounded and enabled to be pulled down, so that the DC-DC chip is in the off state. When the real-time voltage signal is less than the second reference voltage signal, which is regarded as 0 and recorded as a non-over-voltage state. The voltage at the G terminal of the MOS transistor Q25 is pulled down, which is consistent with the voltage between the S terminal, and the SS/EN pin is kept connected to the triode Q24. A hysteresis circuit, namely, a diode D25, a resistor R141, a resistor R138 and VDD, is disposed between the terminal 7 and the terminal 5 of the voltage comparator U19B, and the hysteresis circuit has a feedback function to prevent frequent over-voltage disconnection of the circuit caused by voltage fluctuation.

After the connection switch MOS transistor Q25 and the power supply switch triode Q24 are all turned on, the DC-DC chip is powered on to drive two groups of the full-bridge MOS group to be alternately turned on, so that the DC power of the DC-DC+input is connected to the transformer after the two groups are alternately turned on, realizing the function of converting DC into a pulse.

After the DC-DC chip is turned on, whether the voltage signal output by the DC-DC+satisfies the preset condition is still determined in real time in the above manner, and the connection switch and the power supply switch are turned off when the voltage signal output by the DC-DC+does not satisfy the preset condition, to avoid burning the full-bridge MOS group.

An embodiment of the present disclosure further provides a charging and distribution system, including the circuit for protecting the MOS group shown in FIG. 2 or FIG. 3.

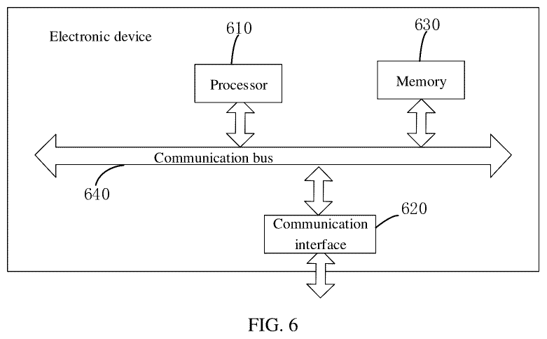

FIG. 6 is a schematic structural diagram of an electronic device according to an embodiment of the present disclosure. As shown in FIG. 6, the electronic device may include at least one processor, and at least one memory in communication with the processing unit. The memory stores program instructions executable by the processing unit, and the processor, when invoking the program instructions, is configured to perform the method for protecting the MOS group provided in the above embodiments.

The electronic device may be a device capable of conducting intelligent dialogue with a user, such as a cloud server. The specific form of the electronic device is not limited by the embodiments of the present disclosure. It may be understood that the electronic device herein is the machine mentioned in the method embodiments.

FIG. 6 shows a block diagram of an exemplary electronic device suitable for implementing embodiments of the present disclosure. The electronic device shown in FIG. 6 is merely an example, and should not bring any limitation to the function and scope of use of the embodiments of the present disclosure.

As shown in FIG. 6, the electronic device is represented in the form of a general-purpose computing device. Components of the electronic device may include, but are not limited to: one or more processors 610, a communication interface 620, a memory 630, and a communications bus 640 that connects different system components (including the memory 630, the communications interface 620, and the processor 610).

The communications bus 640 represents one or more of several types of bus structures, including a memory bus or a memory controller, a peripheral bus, an accelerated graphics port, a processor, or a local bus using any of a variety of bus structures. For example, these architectures include but are not limited to Industry Standard Architecture (ISA) Bus, Micro Channel Architecture (MAC) Bus, Enhanced ISA Bus, Video Electronics Standards Association (VESA) Local Bus, and Peripheral Component Interconnect (PCI) Bus.

The electronic device typically includes a variety of computer system readable media. These media may be any available media that can be accessed by an electronic device, including volatile and non-volatile media, removable and non-removable media.

The memory 630 may include a computer system readable medium in a form of a volatile memory, for example, a Random Access Memory (RAM) and/or a cache memory. The electronic device may further include other removable/non-removable, volatile/non-volatile computer system storage media. The memory 630 may include at least one program product having a set (e.g., at least one) of program modules configured to perform functions of the embodiments of the present disclosure.

A program/utility with a set (at least one) of program modules may be stored in the memory 630, such program modules including, but not limited to, an operating system, one or more application programs, other program modules, and program data, each or some combination of which may include an implementation of a network environment. The program modules generally perform functions and/or methods in the embodiments described in the present disclosure.

The processor 610 executes various functional applications and data processing by running programs stored in the memory 630, such as implementing the method for protecting the MOS group provided in the embodiments shown in the present disclosure.

Embodiments of the present disclosure provide a non-transitory computer-readable storage medium on which computer instructions are stored. The computer instructions enable a computer to implement the method for protecting the MOS group provided by the embodiments shown in the present disclosure.

The non-transitory computer-readable storage medium described above may use any combination of one or more computer-readable media. The computer-readable media may be computer-readable signal media or computer-readable storage media. The computer-readable storage medium may be, for example, but not limited to, an electrical, magnetic, optical, electromagnetic, infrared, or semiconductor system, apparatus, or device, or any combination thereof. More specific examples (a non-exhaustive list) of the computer-readable storage media include: an electrical connection with one or more wires, a portable computer disk, a hard disk, a random access memory (RAM), and a read only memory (ROM), an erasable programmable read only memory (EPROM) or a flash memory, an optical fiber, a portable compact disk read only memory (CD-ROM), an optical storage device, a magnetic storage device, or any suitable combination of the above devices. In this document, a computer-readable storage medium may be any tangible medium containing or storing a program that may be used by or in connection with an instruction execution system, apparatus, or device.

A computer-readable signal medium may include data signals propagated in baseband or as part of a carrier wave, which carry computer-readable program code therein. Such propagated data signals may take a variety of forms, including, but not limited to, electromagnetic signals, optical signals, or any suitable combination of the above. The computer-readable signal medium may further be any computer-readable medium other than a computer-readable storage medium that can transmit, propagate, or transport a program for use by or in connection with an instruction execution system, apparatus, or device.

Program codes contained on the computer-readable medium may be transmitted using any appropriate medium, including, but not limited to, wireless, wire, optical cable, RF, etc., or any suitable combination of the above.

Computer program codes for performing the operations of the present disclosure may be written in one or more programming languages or combinations thereof, including object-oriented programming languages such as Java, Smalltalk, C++, and conventional procedural programming languages such as the “C” language or similar programming languages. The program codes may execute entirely on a user's computer, partially on a user's computer, as a stand-alone software package, partially on a user's computer and partially on a remote computer, or entirely on a remote computer or server. In cases involving a remote computer, the remote computer may be connected to the user's computer via any type of network, including a local area network (LAN) or a wide area network (WAN), or may connect to an external computer (e.g., via the Internet using an Internet service provider).

Specific embodiments of the present disclosure are described above. Other embodiments are within the scope of the attached claims. In some cases, actions or steps recited in the claims can be performed in a different order than in the embodiments and still achieve the desired results. Additionally, the processes depicted in the figures do not necessarily require a particular order or sequential order shown to achieve the desired result. In certain implementations, multitasking and parallel processing are further possible or may be advantageous.

In addition, the terms “first” and “second” are used for descriptive purposes only, and cannot be understood as indicating or implying relative importance or implicitly indicating the number of technical features indicated. Therefore, features defined by “first” and “second” may explicitly or implicitly include at least one of the features. In the description of the present disclosure, “a plurality of” means at least two, for example, two, three, and the like, unless specifically defined otherwise.

Any process or method description in a flowchart or otherwise described herein may be understood as representing a module, a segment, or portions of codes including one or more executable instructions for implementing steps of a custom logic function or process, and the scope of preferred embodiments of the present disclosure includes further implementations, where the functions may be performed in a different order than shown or discussed, including substantially based on the functions involved, which should be understood by those skilled in the art to which the embodiments of the present disclosure belong.

Depending on the context, the word “if” as used herein can be interpreted as “when”, “while” or “in response to determination” or “in response to detection”. Similarly, depending on the context, the phrase “if determined” or “if detected (statement of a condition or event)” can be interpreted as “when determined” or “in response to determination” or “when detected (statement of a condition or event)” or “in response to detection (statement of a condition or event)”.

It should be noted that the terminal in the embodiments of the present disclosure may include, but is not limited to, a personal computer (PC), a personal digital assistant (PDA), a wireless handheld device, a tablet computer, a mobile phone, a MP3 player, a MP4 player, etc.

In the embodiments provided in the present disclosure, it should be understood that the disclosed systems, apparatuses, and methods may be implemented in other ways. For example, the apparatus embodiments described above are merely illustrative, for example, the division of the units is merely a logical function division, and there may be another division manner in actual implementation. For example, a plurality of units or components may be combined or integrated into another system, or some features may be ignored or not executed. In addition, coupling or direct coupling or communication connecting shown or described above may be indirect coupling or communication connecting through some interfaces, apparatus or units, and may be in an electrical, mechanical or other form.

Further, each functional unit in the embodiments of the present disclosure may be integrated into one processing unit, or each unit may exist alone physically, or two or more units may be integrated into one unit. The integrated unit described above can be implemented in a form of hardware or in a form of hardware and software functional units.

The integrated unit implemented in a form of software functional device described above may be stored in the computer-readable storage medium. The above software function unit is stored in a storage medium, and includes a plurality of instructions to enable a computer apparatus (which may be a personal computer, a server, a network apparatus, or the like) or a processor to perform some steps of the methods in the embodiments of the present disclosure.

The above descriptions are merely preferred embodiments of the present disclosure and are not intended to limit the present disclosure. It should be noted that any modifications, equivalent substitutions, improvements, and the like made within the spirit and principle of the present disclosure shall fall within the protection scope of the present disclosure.

What is claimed is:

1. A method for protecting a metal oxide semiconductor (MOS) group, comprising:
disconnecting a power supply switch to set a direct current to direct current (DC-DC) chip in an off state;
controlling an input of a target power supply, and determining whether a voltage signal of the target power supply satisfies a preset condition;
when determining that the voltage signal of the target power supply satisfies the preset condition, turning on the power supply switch and supplying, by a chip power supply, power to the DC-DC chip, wherein when the voltage signal of the target power supply satisfies the preset condition, a connection switch is turned on, and the DC-DC chip is connected to a power supply circuit; and
when the DC-DC chip is powered on and activated, turning on a target MOS group and converting a DC voltage signal output by the target power supply into a pulse electrical signal.

2. The method according to claim 1, wherein said when the voltage signal of the target power supply satisfies the preset condition, the connection switch is turned on comprises:
when the voltage signal of the target power supply is both in a non-over-voltage state and in a non-under-voltage state, the voltage signal of the target power supply satisfies the preset condition, and the connection switch is turned on.

3. The method according to claim 1, wherein said determining whether the voltage signal of the target power supply satisfies the preset condition comprises:
collecting, by a sampling circuit, the voltage signal of the target power supply; and
determining that the voltage signal of the target power supply satisfies the preset condition in response to the voltage signal of the target power supply being within an operating voltage range.

4. The method according to claim 1, wherein after the DC-DC chip is powered on and activated, the method further comprises:
when the voltage signal of the target power supply does not satisfy the preset condition, disconnecting the power supply switch or the connection switch and turning on the DC-DC chip;
wherein the power supply switch is turned off under control of a micro control unit (MCU), and the connection switch is automatically turned off based on a circuit structure.

5. The method according to claim 1, wherein said turning on the power supply switch and supplying power to the DC-DC chip comprises:
turning on the power supply switch to supply power to the DC-DC chip after a preset time when determining that the voltage signal satisfies the preset condition.

6. A circuit for protecting a metal oxide semiconductor (MOS) group, comprising:
a micro control unit (MCU) configured to control a power supply switch to be turned off before determining whether a voltage signal of a target power supply satisfies a preset condition, and control the power supply switch to be turned on after determining that the voltage signal of the target power supply satisfies the preset condition;
a connection switch configured to be turned on when the voltage signal of the target power supply satisfies the preset condition, and connect a direct current to direct current (DC-DC) chip to a power supply circuit to supply power to the DC-DC chip; and
the power supply switch, configured to be turned off or turned on under control of the MCU to supply power to the DC-DC chip through a chip power supply;
wherein when the DC-DC chip is powered on and activated, a target MOS group is turned on, and a DC voltage signal output by the target power supply is converted into a pulse electrical signal.

7. The circuit according to claim 6, wherein an input end of the connection switch is connected to a determination circuit, and the determination circuit comprises:
an under-voltage determination circuit configured to output a low-level signal to the connection switch when determining that the voltage signal is in a non-under-voltage state, and output a high-level signal to the connection switch when determining that the voltage signal is in an under-voltage state;
an over-voltage determination circuit configured to output the low-level signal to the connection switch when determining that the voltage signal is in a non-over-voltage state, and output the high-level signal to the connection switch when determining that the voltage signal is in an over-voltage state; and
the connection switch configured to be turned on when the under-voltage determination circuit and the over-voltage determination circuit simultaneously output the low-level signal, and to be turned off otherwise.

8. The circuit according to claim 7, wherein the under-voltage determination circuit comprises a first voltage comparator, and the over-voltage determination circuit comprises a second voltage comparator;
wherein a first input end of the first voltage comparator is connected to the target power supply, a second input end of the first voltage comparator is connected to the chip power supply, and the first voltage comparator is configured to compare a voltage signal output by the target power supply with a first reference voltage signal of the chip power supply to determine whether the target power supply is in the under-voltage state; and
wherein a first input end of the second voltage comparator is connected to the chip power supply, a second input end of the second voltage comparator is connected to the target power supply, and the second voltage comparator is configured to compare a voltage signal output by the target power supply with a second reference voltage signal of the chip power supply to determine whether the target power supply is in the over-voltage state.

9. The circuit according to claim 7, wherein the under-voltage determination circuit and the over-voltage determination circuit further comprise: a hysteresis circuit configured to feed back a reference voltage signal input by the chip power supply to prevent frequent under-voltage disconnections of the circuit caused by voltage fluctuation.

10. The circuit according to claim 6, further comprising: a sampling circuit connected between the target power supply and the MCU, and configured to collect the voltage signal of the target power supply, and send the collected voltage signal to the MCU.

11. The circuit according to claim 6, wherein an input end of the power supply circuit is the chip power supply, and an output end of the power supply circuit is connected to the power supply switch, and the power supply circuit is configured to supply power to the DC-DC chip when the power supply switch and the connection switch are turned on.

12. A device for protecting a metal oxide semiconductor (MOS) group, comprising:
at least one processor; and
at least one memory in communication with the processor,
wherein the at least one memory stores program instructions executable by the processor, and the processor, when invoking the program instructions, is configured to execute the method according to claim 1.
